(19) United States
(12) Patent Application Publication
(10) Pub. No.: US 2026/0090077 A1
(43) Pub. Date: Mar. 26, 2026

(54) SEMICONDUCTOR DEVICE AND METHOD FOR MANUFACTURING SAME

(71) Applicants: Kabushiki Kaisha Toshiba, Kawasaki-shi (JP); Toshiba Electronic Devices & Storage Corporation, Kawasaki-shi (JP)

(72) Inventor: Yasuhiro ISOBE, Narashino Chiba (JP)

(21) Appl. No.: 19/409,636

(22) Filed: Dec. 4, 2025

Related U.S. Application Data
(63) Continuation of application No. PCT/JP2023/034096, filed on Sep. 20, 2023.

(51) Int. Cl. H10D 84/83; H01L 23/00; H10D 30/01; H10D 30/47; H10D 62/10; H10D 62/824; H10D 64/00; H10D 84/01

(52) U.S. Cl. CPC H10D 84/83; H10D 30/015; H10D 30/475; H10D 62/102; H10D 62/824; H10D 64/112; H10D 64/117; H10D 84/0149; H10W 72/50; H10W 90/755

(57) ABSTRACT

A semiconductor device includes a substrate; a first conductive member located on a portion of a surface of the substrate; a plurality of nitride semiconductor layers located on the substrate and on the first conductive member, the plurality of nitride semiconductor layers being separated from each other; a source electrode located on each of the nitride semiconductor layers; a drain electrode located on each of the nitride semiconductor layers; a gate electrode located on each of the nitride semiconductor layers; and a second conductive member extending between the first conductive member and the source electrode inside each of the nitride semiconductor layers, the second conductive member being electrically connected to the first conductive member and the source electrode.

### CROSS-REFERENCE TO RELATED APPLICATION

This is a continuation application of International Application PCT/JP2023/034096, filed on Sep. 20, 2023; the entire contents of which are incorporated herein by reference.

### FIELD

Embodiments described herein relate generally to a semiconductor device and a method for manufacturing a semiconductor device.

### BACKGROUND

A HEMT (High Electron Mobility Transistor) is a known power device that uses a gallium nitride material. For example, when a half-bridge circuit including two GaN HEMTs is formed on the same wafer, a negative voltage may be applied to the back surface of the high-side element when the low-side element is off, resulting in an effective back gate effect that may increase the on-resistance.

### BRIEF DESCRIPTION OF THE DRAWINGS

FIG. 1 is a schematic plan view of a semiconductor device of an embodiment;

FIG. 2 is a schematic plan view of an active region of the semiconductor device of the embodiment;

FIG. 3 is a line A-A cross-sectional view of FIG. 2;

FIG. 4 is a schematic plan view showing a pattern example of a first conductive member of the semiconductor device of the embodiment;

FIG. 5 is a line B-B cross-sectional view of FIG. 1;

FIGS. 6A and 6B are schematic cross-sectional views showing a method for manufacturing a semiconductor device of an embodiment;

FIGS. 7A and 7B are schematic cross-sectional views showing the method for manufacturing the semiconductor device of the embodiment; and

FIG. 8 is a schematic plan view of a semiconductor device according to a modification of the embodiment.

### DETAILED DESCRIPTION

According to an embodiment, a semiconductor device includes: a substrate; a first conductive member located on a portion of a surface of the substrate; multiple nitride semiconductor layers that are located on the substrate and on the first conductive member and separated from each other; a source electrode located on each of the nitride semiconductor layers; a drain electrode located on each of the nitride semiconductor layers; a gate electrode located on each of the nitride semiconductor layers; and a second conductive member that extends between the first conductive member and the source electrode inside each of the nitride semiconductor layers and is electrically connected to the first conductive member and the source electrode.

Embodiments will now be described with reference to the drawings. The same configurations are marked with the same reference numerals in the drawings.

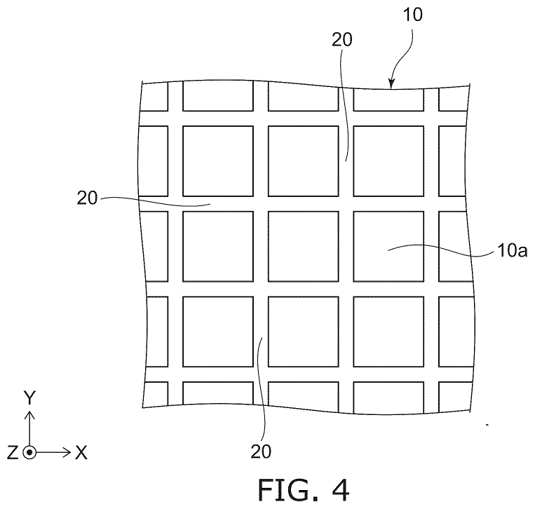

As shown in FIG. 4, a semiconductor device 1 of the embodiment includes a substrate 10, and a first conductive member 20 located on a portion of a surface 10a of the substrate 10. Two directions that are parallel to the surface 10a of the substrate 10 and cross each other (in the example, are orthogonal to each other) are taken as a first direction X and a second direction Y. A direction that is orthogonal to the first and second directions X and Y and perpendicular to the surface 10a of the substrate 10 is taken as a third direction Z. For example, the first conductive member 20 has a lattice-shaped planar pattern extending along the first and second directions X and Y. The first conductive member 20 directly contacts the surface 10a of the substrate 10.

The substrate 10 is, for example, a silicon substrate. A sapphire substrate may be used as the substrate 10. The first conductive member 20 can include, for example, at least one selected from the group consisting of nickel, titanium nitride, and tungsten. When a silicon substrate is used as the substrate 10, the first conductive member 20 can include a nickel silicide.

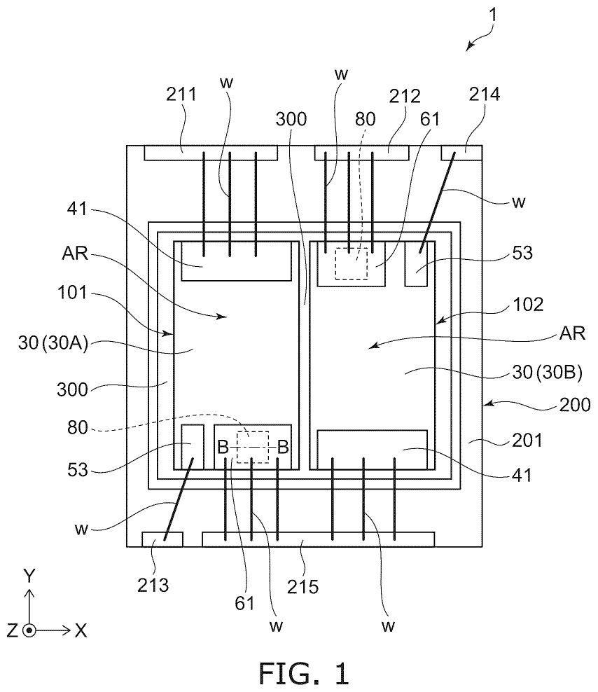

The semiconductor device 1 of the embodiment includes multiple nitride semiconductor elements. In the example shown in FIG. 1, a first nitride semiconductor element 101 and a second nitride semiconductor element 102 are shown as multiple nitride semiconductor elements. The first nitride semiconductor element 101 and the second nitride semiconductor element 102 are, for example, lateral HEMT elements.

The first nitride semiconductor element 101 and the second nitride semiconductor element 102 are located on the substrate 10 and on the first conductive member 20 and include multiple nitride semiconductor layers 30 that are separated from each other. The first nitride semiconductor element 101 includes a first nitride semiconductor layer 30A; and the second nitride semiconductor element 102 includes a second nitride semiconductor layer 30B. In the specification, the first nitride semiconductor layer 30A and the second nitride semiconductor layer 30B may be referred to as simply the nitride semiconductor layer 30 without differentiation. Three or more element-separated nitride semiconductor layers 30 may be located on the substrate 10. The first conductive member 20 is electrically separated for each nitride semiconductor element. The first conductive member 20 below the first nitride semiconductor element 101 and the first conductive member 20 below the second nitride semiconductor element 102 are electrically separated.

The first nitride semiconductor layer 30A and the second nitride semiconductor layer 30B are separated from each other on the substrate 10 by an element separating part 300. The element separating part 300 continuously surrounds the first nitride semiconductor layer 30A and the second nitride semiconductor layer 30B. The element separating part 300 is an insulating member and can include, for example, a silicon oxide film.

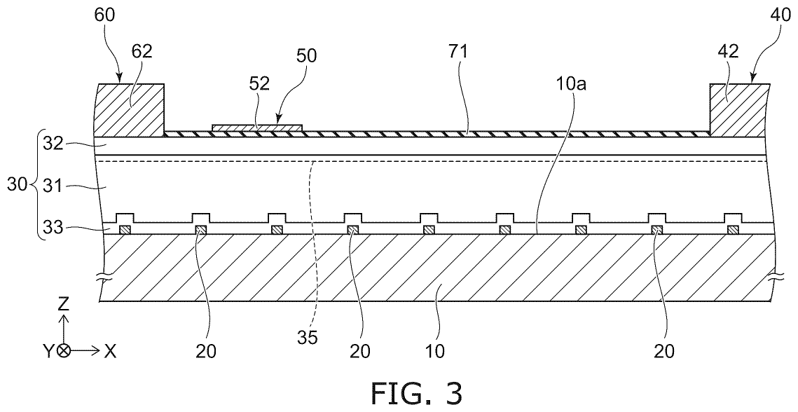

As shown in FIG. 3, the nitride semiconductor layer 30 includes a first layer 31 and a second layer 32. The second layer 32 is located on the first layer 31 in the third direction Z. The bandgap of the second layer 32 is wider than the bandgap of the first layer 31. For example, the first layer 31 is a gallium nitride (GaN) layer; and the second layer 32 is an aluminum gallium nitride (AlGaN) layer. A two-dimensional electron gas 35 has a distribution in the first layer 31 at the vicinity of the interface with the second layer 32.

The nitride semiconductor layer 30 also may include a third layer 33. The third layer 33 is located between the substrate 10 and the first layer 31 and between the first conductive member 20 and the first layer 31. The third layer 33 functions as a buffer layer that reduces the crystal defects of the nitride semiconductor layer 30. For example, an aluminum nitride (AlN) layer can be used as the third layer 33.

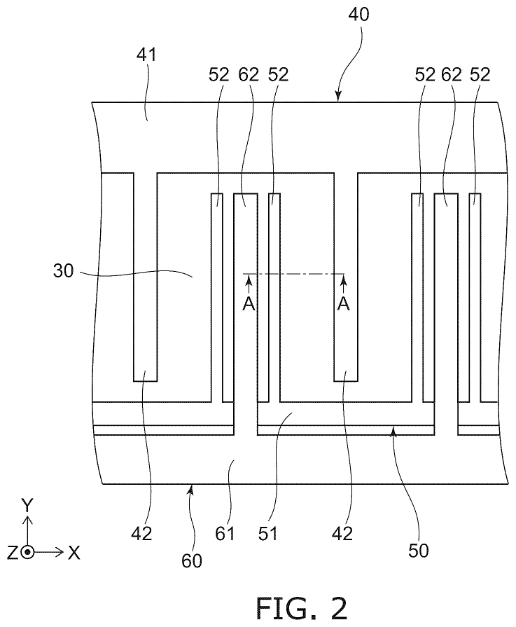

The first nitride semiconductor element 101 and the second nitride semiconductor element 102 each include active regions AR. FIG. 2 is a schematic plan view of the active region AR. FIG. 3 is a line A-A cross-sectional view of FIG. 2.

The first nitride semiconductor element 101 and the second nitride semiconductor element 102 each include a source electrode 60, a drain electrode 40, a gate electrode 50, and a first insulating film 71. These components are located on the nitride semiconductor layer 30.

As shown in FIG. 2, the source electrode 60 includes source finger parts 62 and a source pad part 61. The source pad part 61 extends in the first direction X. The multiple source finger parts 62 extend in the second direction Y from the source pad part 61. As shown in FIG. 3, the source finger part 62 contacts the surface of the nitride semiconductor layer 30 and is electrically connected to the nitride semiconductor layer 30. For example, a stacked structure of titanium (Ti) and aluminum (Al) can be used as the material of the source electrode 60.

As shown in FIG. 2, the drain electrode 40 includes drain finger parts 42 and a drain pad part 41. The drain pad part 41 extends in the first direction X. The multiple drain finger parts 42 extend in the second direction Y from the drain pad part 41 toward the source pad part 61. As shown in FIG. 3, the drain finger part 42 contacts the surface of the nitride semiconductor layer 30 and is electrically connected to the nitride semiconductor layer 30. For example, the same material as the source electrode 60 can be used as the material of the drain electrode 40.

As shown in FIG. 3, the first insulating film 71 is located on the surface of the nitride semiconductor layer 30 between the source finger part 62 and the drain finger part 42. For example, a silicon oxide film can be used as the first insulating film 71.

As shown in FIG. 2, the gate electrode 50 includes gate finger parts 52 and a gate wiring part 51. The gate wiring part 51 extends in the first direction X. The multiple gate finger parts 52 extend in the second direction Y from the gate wiring part 51. For example, the gate finger parts 52 extend from the gate wiring part 51 toward the drain pad part 41. The gate finger part 52 is positioned between the drain finger part 42 and the source finger part 62 in the first direction X. Two gate finger parts 52 are positioned between two drain finger parts 42 adjacent to each other in the first direction X. One source finger part 62 is positioned between two gate finger parts 52 adjacent to each other in the first direction X. For example, a stacked structure of nickel (Ni) and gold (Au), titanium nitride (TiN), or polycrystalline silicon (Poly-Si) can be used as the material of the gate electrode 50.

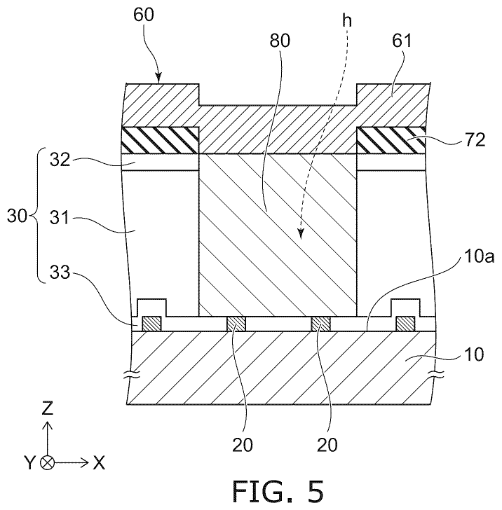

As shown in FIG. 3, the gate finger part 52 is located on the first insulating film 71. The distance in the first direction X between the drain finger part 42 of the drain electrode 40 and the gate finger part 52 of the gate electrode 50 is greater than the distance in the first direction X between the source finger part 62 of the source electrode 60 and the gate finger part 52 of the gate electrode 50. The breakdown voltage can be increased thereby. The first nitride semiconductor element 101 and the second nitride semiconductor element 102 each include a second conductive member 80 shown in FIG. 5. The second conductive member 80 has a columnar shape inside the nitride semiconductor layer 30. The second conductive member 80 extends between the first conductive member 20 and the source electrode 60 and is electrically connected to the first conductive member 20 and the source electrode 60. For example, nickel (Ni), titanium (Ti), aluminum (Al), etc., can be used as the material of the second conductive member 80.

The second conductive member 80 is located inside a hole h formed in the nitride semiconductor layer 30. The first conductive member 20 is exposed at the bottom part of the hole h. The second conductive member 80 contacts the exposed first conductive member 20. For example, the second conductive member 80 contacts at least one first conductive member 20 among multiple first conductive members 20 extending in a lattice shape. For example, the multiple first conductive members 20 have a continuous lattice shape, and so the multiple first conductive members 20 are electrically connected to the source electrode 60 via the second conductive member 80. The upper surface of the second conductive member 80 contacts the source pad part 61 of the source electrode 60.

The first nitride semiconductor element 101 and the second nitride semiconductor element 102 each can include a second insulating film 72 located between the source pad part 61 and the surface of the nitride semiconductor layer 30. The second insulating film 72 also is located between the drain pad part 41 and the surface of the nitride semiconductor layer 30 and between the gate wiring part 51 and the surface of the nitride semiconductor layer 30. The second insulating film 72 also is located between a gate pad part 53 (described below and shown in FIG. 1) and the surface of the nitride semiconductor layer 30. For example, a silicon oxide film can be used as the second insulating film 72.

As shown in FIG. 1, the semiconductor device of the embodiment can include a support member 200 supporting the first nitride semiconductor element 101 and the second nitride semiconductor element 102. The support member 200 includes an insulating part 201 and a conductive part. For example, a resin can be used as the material of the insulating part 201. The conductive part is, for example, a leadframe that includes a first lead 211, a second lead 212, a third lead 213, a fourth lead 214, and a fifth lead 215. For example, iron (Fe), nickel (Ni), and/or copper (Cu) can be used as the material of the first lead 211, the second lead 212, the third lead 213, the fourth lead 214, and the fifth lead 215.

For example, the first nitride semiconductor element 101 and the second nitride semiconductor element 102 are configured in a half-bridge circuit. The first nitride semiconductor element 101 functions as the high-side element; and the second nitride semiconductor element 102 functions as the low-side element. The semiconductor device 1 may include three or more nitride semiconductor elements on the substrate 10.

As shown in FIG. 1, the drain pad part 41 that is located on the first nitride semiconductor layer 30A of the first nitride semiconductor element 101 is electrically connected to the first lead 211 via a wire w. The first lead 211 is electrically connected to a power supply. For example, a gold wire can be used as the wire w.

The source pad part 61 that is located on the second nitride semiconductor layer 30B of the second nitride semiconductor element 102 is electrically connected to the second lead 212 via the wire w. The second lead 212 is grounded. The gate pad part 53 that is electrically connected to the gate wiring part 51 of the first nitride semiconductor element 101 is located on the first nitride semiconductor layer 30A of the first nitride semiconductor element 101; and the gate pad part 53 of the first nitride semiconductor element 101 is electrically connected to the third lead 213 via the wire w.

The gate pad part 53 that is electrically connected to the gate wiring part 51 of the second nitride semiconductor element 102 is located on the second nitride semiconductor layer 30B of the second nitride semiconductor element 102; and the gate pad part 53 of the second nitride semiconductor element 102 is electrically connected to the fourth lead 214 via the wire w.

The source pad part 61 that is located on the first nitride semiconductor layer 30A of the first nitride semiconductor element 101 is electrically connected to the fifth lead 215 via the wire w. The drain pad part 41 that is located on the second nitride semiconductor layer 30B of the second nitride semiconductor element 102 is electrically connected to the fifth lead 215 via the wire w. Accordingly, the source electrode 60 of the first nitride semiconductor element 101 is electrically connected to the drain electrode 40 of the second nitride semiconductor element 102 by the fifth lead 215. The fifth lead 215 is an output terminal of the half-bridge circuit.

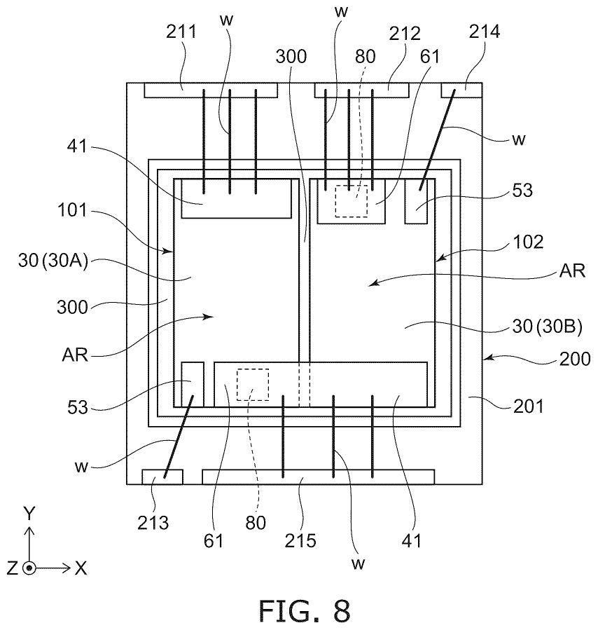

Or, as shown in FIG. 8, the source electrode 60 of the first nitride semiconductor element 101 and the drain electrode 40 of the second nitride semiconductor element 102 may be electrically connected by connecting the source pad part 61 of the first nitride semiconductor element 101 and the drain pad part 41 of the second nitride semiconductor element 102 to straddle the element separating part 300 above the nitride semiconductor layer 30.

The upper surface of the semiconductor device 1 shown in FIG. 1 is covered with an encapsulating member made of, for example, a resin material.

According to the embodiment, the multiple nitride semiconductor elements 101 and 102 can be realized on the same substrate 10; and the potential of the source electrode 60 can be applied to the substrate 10 via the second and first conductive members 80 and 20. By fixing the potential of the substrate 10 to the source potential, the multiple nitride semiconductor elements 101 and 102 can operate without being affected by the other nitride semiconductor element. For example, an increase of the on-resistance due to a negative voltage applied to the back surface of the high-side element (the first nitride semiconductor element 101) when the low-side element (the second nitride semiconductor element 102) is off can be suppressed. The source potential is, for example, a ground potential.

As shown in FIG. 4, for example, the first conductive member 20 extends in a lattice shape at the surface 10a of the substrate 10; and by a portion of the lattice-shaped first conductive member 20 contacting the second conductive member 80, the lattice-shaped first conductive member 20 can apply the source potential to a wider area of the surface 10a of the substrate 10 than the location of the second conductive member 80. For example, the planar pattern of the first conductive member 20 may be multiple stripe patterns extending in the first direction X or the second direction Y. In such a case, the stripe-shaped first conductive members 20 can be connected to each other by at least one first conductive member 20 extending in a direction crossing the stripe-shaped first conductive members 20.

As shown in FIG. 3, the first conductive member 20 also is positioned under the drain finger part 42 of the drain electrode 40 and under the gate finger part 52 of the gate electrode 50. As a result, a field plate effect can be applied to the nitride semiconductor layer 30 from the backside; and concentration of the electric field can be relaxed.

A method for manufacturing a semiconductor device of an embodiment will now be described.

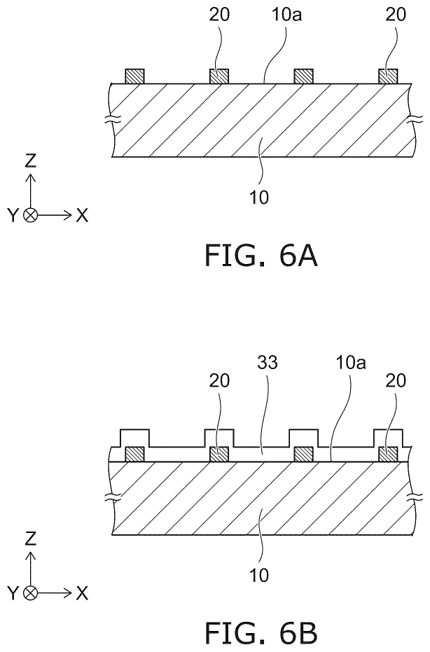

As shown in FIG. 6A, the method for manufacturing the semiconductor device of the embodiment includes a process of forming the first conductive member 20 on a portion of the surface 10a of the substrate 10. For example, as described above with reference to FIG. 4, the first conductive member 20 can be formed in a lattice pattern.

After forming the first conductive member 20, the method for manufacturing the semiconductor device of the embodiment includes a process of forming the nitride semiconductor layer 30 on the substrate 10 and on the first conductive member 20.

For example, the nitride semiconductor layer 30 can be formed by MOCVD (metal organic chemical vapor deposition) on the substrate 10, which is a silicon substrate. To favorably grow the nitride semiconductor layer 30 on the substrate 10, it is favorable for the area of the portion of the surface 10a of the substrate 10 where the first conductive member 20 is present to be less than the area of the other portion of the surface 10a of the substrate 10 where the first conductive member 20 is not present.

For example, in the example shown in FIG. 4, the width in the first direction X and the width in the second direction Y of the first conductive member 20 are 0.1 μm; and the distance (the pitch) between the first conductive members 20 adjacent to each other in the first direction X and the distance (the pitch) between the first conductive members 20 adjacent to each other in the second direction Y are 10 μm.

In the process of forming the nitride semiconductor layer 30 as shown in FIG. 6B, for example, the third layer 33 is formed on the surface 10a of the substrate 10 as a buffer layer. The third layer 33 that is grown from the surface 10a of the substrate 10 can grow in the lateral direction on the first conductive member 20 to cover the first conductive member 20. For example, an aluminum nitride layer can be used as the third layer 33.

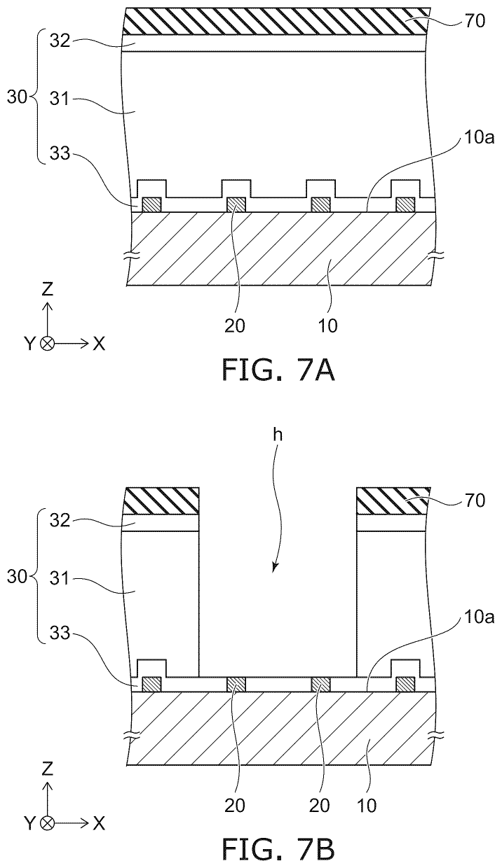

As shown in FIG. 7A, the first layer 31 and the second layer 32 are grown in this order on the third layer 33. An insulating film 70 is formed on the second layer 32. The insulating film 70 can include the first insulating film 71 and the second insulating film 72 described above.

The method for manufacturing the semiconductor device of the embodiment includes a process of dividing the nitride semiconductor layer 30 into a plurality. For example, a trench is formed in the nitride semiconductor layer 30 along the element separating part 300 shown in FIG. 1 by RIE (Reactive Ion Etching). The trench reaches the surface 10a of the substrate 10. The third layer 33 may remain between the first conductive members 20 at the bottom part of the trench. The trench divides the nitride semiconductor layer 30 into a plurality. In the example shown in FIG. 1, the nitride semiconductor layer 30 is divided into the first and second nitride semiconductor layers 30A and 30B. An insulating member is filled into the trench. The nitride semiconductor layer 30 may be divided into three or more nitride semiconductor layers.

As shown in FIG. 7B, the method for manufacturing the semiconductor device of the embodiment includes a process of forming the hole h in the nitride semiconductor layer 30 to reach the first conductive member 20. For example, the hole h can be formed by RIE. The trench and the hole can be simultaneously formed. The hole h extends through at least the insulating film 70, the second layer 32, and the first layer 31 in the third direction Z. At least the upper surface of the first conductive member 20 is exposed at the bottom part of the hole h. At least a portion of the side surface of the first conductive member 20 may be exposed at the bottom part of the hole h.

The planar shape of the hole h is, for example, quadrilateral. The planar shape of the hole h may be circular. The width or diameter of the hole h can be, for example, 100 μm. In such a case, for example, about ten of the multiple first conductive members 20 arranged in the first direction X at a spacing (a pitch) of 10 μm can be exposed at the bottom part of the hole h. Similarly, for example, about ten of the multiple first conductive members 20 arranged in the second direction Y at a spacing (a pitch) of 10 μm can be exposed at the bottom part of the hole h. For example, by forming the first conductive member 20 in a lattice pattern at the surface 10a of the substrate 10 and by forming the hole h to have a larger planar size than the pitch of the lattice of the first conductive member 20, the first conductive member 20 can be easily exposed at the bottom part of the hole h by forming the hole h anywhere in the nitride semiconductor layer 30 without the need for a mark or the like.

The method for manufacturing the semiconductor device of the embodiment includes a process of forming the second conductive member 80 inside the hole h. As shown in FIG. 5, the second conductive member 80 contacts the first conductive member 20 at the bottom part of the hole h.

The method for manufacturing the semiconductor device of the embodiment includes a process of forming the source electrode 60 on the nitride semiconductor layer 30 to be electrically connected to the second conductive member 80. In the example shown in FIG. 5, the source pad part 61 of the source electrode 60 contacts the upper surface of the second conductive member 80. As a result, the first conductive member 20 is electrically connected to the source electrode 60 via the second conductive member 80.

In the process of forming the first conductive member 20, it is favorable for the first conductive member 20 to include nickel when the substrate 10 is a silicon substrate. After forming the first conductive member 20, the first conductive member 20 can be nickel-silicided by thermally reacting the silicon of the substrate 10 and the nickel of the first conductive member 20. Because the lattice constant of nickel silicide is close to the lattice constant of silicon, the nitride semiconductor layer 30 can be easily formed with reduced defects even on the first conductive member 20 in the process of forming the nitride semiconductor layer 30.

For example, the heat applied in the process of forming the nitride semiconductor layer 30 by MOCVD can be used to nickel-silicide the first conductive member 20 while growing the nitride semiconductor layer 30 on the nickel silicide.

By reducing the thickness (the height) in the third direction Z of the first conductive member 20, the flatness of the nitride semiconductor layer 30 is easily ensured. It is desirable for the thickness of the first conductive member 20 to be such that the first conductive member 20 reliably remains without being consumed when etching to form the hole h. From such a perspective, it is favorable for the thickness (the height) in the third direction Z of the first conductive member 20 to be not less than 10 nm and not more than 100 nm.

While certain embodiments of the inventions have been described, these embodiments have been presented by way of example only, and are not intended to limit the scope of the inventions. These novel embodiments may be embodied in a variety of other forms; and various omissions, substitutions, and changes may be made without departing from the spirit of the inventions. Such embodiments and their modifications are within the scope and spirit of the inventions, and are within the scope of the inventions described in the claims and their equivalents.

What is claimed is:

1. A semiconductor device, comprising:
a substrate;
a first conductive member located on a portion of a surface of the substrate;
a plurality of nitride semiconductor layers located on the substrate and on the first conductive member, the plurality of nitride semiconductor layers being separated from each other;
a source electrode located on each of the nitride semiconductor layers;
a drain electrode located on each of the nitride semiconductor layers;
a gate electrode located on each of the nitride semiconductor layers; and
a second conductive member extending between the first conductive member and the source electrode inside each of the nitride semiconductor layers, the second conductive member being electrically connected to the first conductive member and the source electrode.

2. The semiconductor device according to claim 1, wherein
an area of the portion of the surface of the substrate where the first conductive member is present is less than an area of another portion of the surface of the substrate where the first conductive member is not present.

3. The semiconductor device according to claim 1, wherein
the first conductive member extends along two directions parallel to the surface of the substrate, and
the two directions cross each other.

4. The semiconductor device according to claim 1, wherein
the nitride semiconductor layers each include a first layer and a second layer,
the second layer is located on the first layer, and
the second layer has a wider bandgap than the first layer.

5. The semiconductor device according to claim 1, wherein
the plurality of nitride semiconductor layers includes a first nitride semiconductor layer and a second nitride semiconductor layer, and
the source electrode located on the first nitride semiconductor layer is electrically connected to the drain electrode located on the second nitride semiconductor layer.

6. The semiconductor device according to claim 1, wherein
the first conductive member also is positioned under at least one of the drain electrodes and under at least one of the gate electrodes.

7. The semiconductor device according to claim 1, wherein the substrate is a silicon substrate, and the first conductive member includes a nickel silicide.

8. The semiconductor device according to claim 1, wherein
a distance between the drain electrode and the gate electrode is greater than a distance between the source electrode and the gate electrode.

9. A method for manufacturing a semiconductor device, the method comprising:
forming a first conductive member on a portion of a surface of a substrate;
forming a nitride semiconductor layer on the substrate and on the first conductive member;
dividing the nitride semiconductor layer into a plurality;
forming a hole in each of the nitride semiconductor layers, the hole reaching the first conductive member;
forming a second conductive member inside each of the holes, the second conductive member contacting the first conductive member; and
forming a source electrode on each of the nitride semiconductor layers, the source electrode being electrically connected to the second conductive member.

10. The method according to claim 9, wherein
the substrate is a silicon substrate,
the first conductive member includes nickel, and
the first conductive member is nickel-silicided by thermally reacting silicon and nickel.

11. The method according to claim 10, wherein
the first conductive member is nickel-silicided by heat applied in the forming of the nitride semiconductor layer.
